(19) United States
(12) Patent Application Publication
(10) Pub. No.: US 2026/0255883 A1
(43) Pub. Date: Aug. 27, 2026

(54) ISOLATED TUNNEL BARRIER FOR MRAM DEVICES

(71) Applicant: INTERNATIONAL BUSINESS MACHINES CORPORATION, Armonk, NY (US)

(72) Inventors: Oscar Van Der Straten, Guilderland Center, NY (US); Pratap Deshmukh, Albany, NY (US); Chih-Chao Yang, Glenmont, NY (US)

(21) Appl. No.: 19/064,566

(22) Filed: Feb. 26, 2025

(51) Int. Cl. H10N 50/10; G11C 11/16; H10N 50/85

(52) U.S. Cl. CPC H10N 50/10; G11C 11/161; H10N 50/85

(57) ABSTRACT

A magnetoresistive-random-access-memory (MRAM) cell structure includes a bottom electrode, a reference layer located on top of the bottom electrode, and a tunnel barrier located on top of the reference layer. The tunnel barrier includes a middle portion and an end portion. The MRAM cell further includes a free layer located on top of the tunnel barrier a top electrode located on top of the free layer, and a spacer that encloses the end portion of the tunnel barrier.

### BACKGROUND

The present invention generally relates to the field of microelectronic devices, and more particularly to isolating the tunnel barrier of an MRAM device.

Nanosheet is the lead device architecture in continuing CMOS scaling are fabricated on the same chip/wafer as MRAM. The height difference between different devices on the same chip/wafer can have different process window margins for opens/shorts. Meaning that the normal process for one part of the device can lead to an open/short being formed in another part of the device.

### BRIEF SUMMARY

Additional aspects and/or advantages will be set forth in part in the description which follows and, in part, will be apparent from the description, or may be learned by practice of the invention.

A magnetoresistive-random-access-memory (MRAM) cell structure includes a bottom electrode, a reference layer located on top of the bottom electrode, and a tunnel barrier located on top of the reference layer. The tunnel barrier includes a middle portion and an end portion. The MRAM cell further includes a free layer located on top of the tunnel barrier a top electrode located on top of the free layer, and a spacer that encloses the end portion of the tunnel barrier.

A magnetoresistive-random-access-memory (MRAM) cell structure includes a bottom electrode and a reference layer located on top of the bottom electrode, where the reference layer includes a horizontal section and a raised section. The MRAM cell further includes a tunnel barrier located on top of the reference layer, where the tunnel barrier includes a middle portion and an end portion. The MRAM cell further includes a free layer located on top of the tunnel barrier, a top electrode located on top of the free layer, and a spacer that encloses the end portion of the tunnel barrier.

A magnetoresistive-random-access-memory (MRAM) cell structure includes a bottom electrode, a reference layer located on top of the bottom electrode, a tunnel barrier located on top of the reference layer, where the tunnel barrier includes a middle portion and an end portion. The MRAM cell further includes a free layer located on top of the tunnel barrier, where the free layer includes a horizontal section and a downward section. The MRAM cell further includes a top electrode located on top of the free layer, and a spacer that encloses the end portion of the tunnel barrier.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a cross-section of an MRAM cell after the initial processing, in accordance with an embodiment of the present invention.

FIG. 2 illustrates a cross-section of the MRAM cell after an etching process, in accordance with an embodiment of the present invention.

FIG. 3 illustrates a cross-section of the MRAM cell after formation of a metal cap layer, in accordance with an embodiment of the present invention.

FIG. 4 illustrates a cross-section of the MRAM cell after an etching of the metal cap layer to form the metal cap, in accordance with an embodiment of the present invention.

FIG. 5 illustrates a cross-section of the MRAM cell after formation of the bottom electrode layer, in accordance with an embodiment of the present invention.

FIG. 6 illustrates a cross-section of the MRAM cell after formation of the initial reference layer, in accordance with an embodiment of the present invention.

FIG. 7 illustrates a cross-section of the MRAM cell after a partial etch of the initial reference layer, in accordance with an embodiment of the present invention.

FIG. 8 illustrates a cross-section of the MRAM cell after formation of a first spacer, in accordance with an embodiment of the present invention.

FIG. 9 illustrates a cross-section of the MRAM cell after etching of the first spacer, the initial reference layer, and the bottom electrode layer, in accordance with an embodiment of the present invention.

FIG. 10 illustrates a cross-section of the MRAM cell after formation of a second spacer, in accordance with an embodiment of the present invention.

FIG. 11 illustrates a cross-section of the MRAM cell after etching back of the second spacer, in accordance with an embodiment of the present invention.

FIG. 12 illustrates a cross-section of the MRAM cell after formation and planarization of a bottom interlayer dielectric layer, in accordance with an embodiment of the present invention.

FIG. 13 illustrates a cross-section of the MRAM cell after formation of the tunnel barrier layer, in accordance with an embodiment of the present invention.

FIG. 14 illustrates a cross-section of the MRAM cell after patterning of the tunnel barrier layer to form the tunnel barrier, in accordance with an embodiment of the present invention.

FIG. 15 illustrates a cross-section of the MRAM cell after formation of a third spacer, in accordance with an embodiment of the present invention.

FIG. 16 illustrates a cross-section of the MRAM cell after patterning of the third spacer, in accordance with an embodiment of the present invention.

FIG. 17 illustrates a cross-section of the MRAM cell after formation of the initial free layer and formation of the top electrode layer, in accordance with an embodiment of the present invention.

FIG. 18 illustrates a cross-section of the MRAM cell after etching of the initial free layer and etching of the top electrode layer, in accordance with an embodiment of the present invention.

FIG. 19 illustrates a cross-section of the MRAM cell after formation of a fourth spacer, in accordance with an embodiment of the present invention.

FIG. 20 illustrates a cross-section of the MRAM cell after etching of the fourth spacer, in accordance with an embodiment of the present invention.

FIG. 21 illustrates a cross-section of the MRAM cell after formation of the top interlayer dielectric layer, in accordance with an embodiment of the present invention.

FIG. 22 illustrates a cross-section of the MRAM cell after formation of a top connector, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards magnetoresistive-random-access-memory (MRAM) cells/arrays, more specifically to isolating the tunnel barrier to protect it from defects being formed from the etching process. The defects can be caused by back scattering from the etching process to form the MRAM cells. The present invention solves the back scattering defects by isolating the end portions of the tunnel barrier layer in a dielectric material, which is accomplished by utilizing a multi-step process to form the MRAM cells. The disclosed invention further solves the issues of filling high aspect ratio valley located between adjacent MRAM cells. The issues with the high aspect ratio valleys is that when filling the space between the individual MRAM cells with a dielectric material can lead to the falling down or collapse of the MRAM cell or the creation of voids in the dielectric material. The present invention prevents the collapse of the MRAM cells by utilizing a multi-stage process to fill the space between the cells.

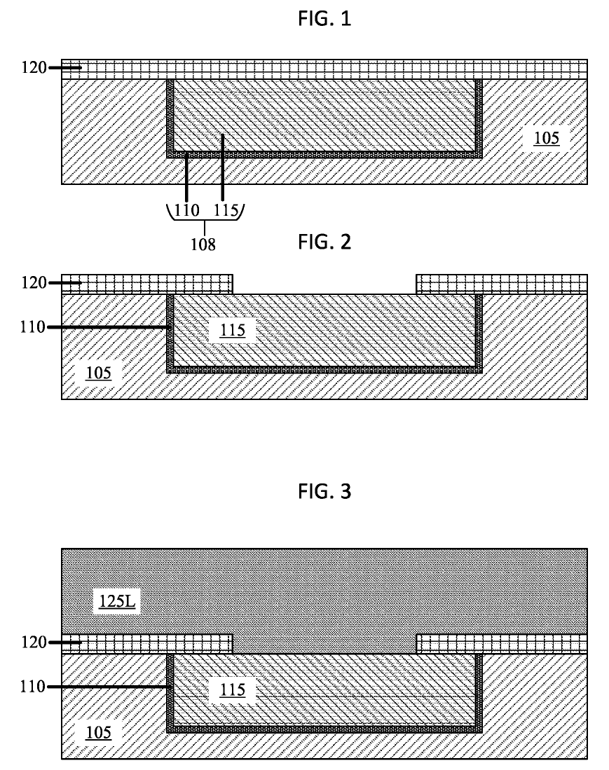

Referring now to FIG. 1, a structure is shown of a magnetoresistive-random-access-memory (MRAM) cell during an intermediate step of a method of formation of the initial layers. FIG. 1 illustrates an initial portion of the MRAM cell that includes an underlying dielectric layer 105, an underlying connector 108, and a dielectric cap 120. The underlying connector 108 includes an underlying liner 110, and an underlying metal component 115. A trench (not shown) which can vary in size is formed in the underlying dielectric layer 105. The trench (not shown) is lined with the underlying liner 110 and filled with conductive metal to form an underlying metal component 115. The dielectric cap 120 is formed on top of the underlying dielectric layer 105, the underlying liner 110, and on top of the underlying metal component 115.

FIG. 2 illustrates the processing stage after patterning of the dielectric cap 120. Dielectric cap 120 is patterned to form trenches that expose a portion of the top surface of the underlying metal component 115. Dielectric cap 120 can be patterned by utilizing a lithography layer with a known etching process.

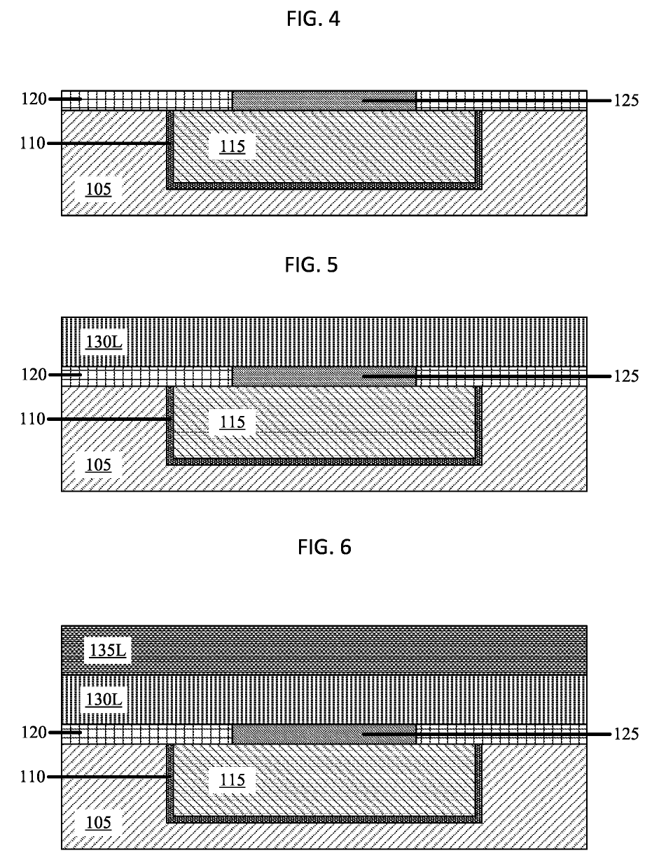

FIG. 3 illustrates the processing stage after formation of the metal cap layer 125L. The metal cap layer 125L is formed on top of the cap layer 120 and fills the trenches in the cap layer 125L. The metal cap layer 125L is in contact with the top surface of the underlying metal component 115. FIG. 4 illustrates the processing stage after the etching or planarization of the metal cap layer 125L to form the metal cap 125. Excess material of the metal cap layer 125L is removed by an etching process or a planarization process. A portion of the metal cap layer 125L remains to form the metal cap 125. The metal cap 125 is located in the trench of the cap layer 120 and is in direct contact with the top surface of the underlying metal component 115.

FIG. 5 illustrates the processing stage after the formation of the bottom electrode layer 130L. A metallization process is utilized to form a bottom electrode layer 130L on top of the cap layer 120 and on top of the metal cap 125. The bottom electrode layer 130L can be selected from a group that includes Nb, NbN, W, WN, Ta, TaN, Ti, TiN, Ru, Cu, W, Mo, Cr, V, Pd, Pt, Rh, Sc, Al, other high melting point metals, other suitable conductive metals, conductive alloys, or a combination thereof. FIG. 6 illustrates the processing stage after the formation of the initial reference layer 135L. The initial reference layer 135L can be selected from a group that includes CoFeB layers with Fe Co, Pt, or Ta.

Typical processing steps to form the initial MRAM layers is to form all the layers (e.g., the bottom electrode, reference layer, the tunnel barrier, free layer, and the top electrode) prior to utilizing an etching process to form the individual MRAM cells. This is an efficient process since there is only one etching step, but utilizing this process can lead to damage to the MRAM relating to back sputtering from the etching process. The back sputtering deposits materials on the sides of the MRAM cells such that the deposited material can form connections between the layers. Additionally, doing a single etch process to the form the MRAM cells can lead to high aspect ratio valleys being formed between adjacent MRAM cells. Filling these high aspect ratio valleys with a dielectric material can lead to the falling down or collapse of the MRAM cells.

In contrast, the present invention initially utilizes an initially etching process to form a bottom section of each of the MRAM cells that are located within the MRAM array. At this processing stage, a low aspect ratio valley is formed between adjacent MRAM cells. These valleys have a low aspect ratio since the height of valleys is equivalent to the low height of the bottom sections of the MRAM cells. After the bottom sections of the MRAM cells are formed, then an initial fill process is utilized to fill the valleys between adjacent MRAM cells. By breaking up the filling of the high aspect ratio valleys into two different stages of filling low aspect ratio valleys (i.e., at different times during processing, for example, the first low aspect valley as emphasized by dashed box 141 and the second low aspect valley as emphasized by dashed box 181) prevents the collapse or falling down of the MRAM cells caused by the dielectric fill process. This will be described in further details below that illustrates the formation of the bottom sections of the MRAM cells and the formation of the bottom interlayer dielectric layer 150 and that illustrates the formation of the top sections of the MRAM cells and the formation of the top interlayer dielectric layer 180.

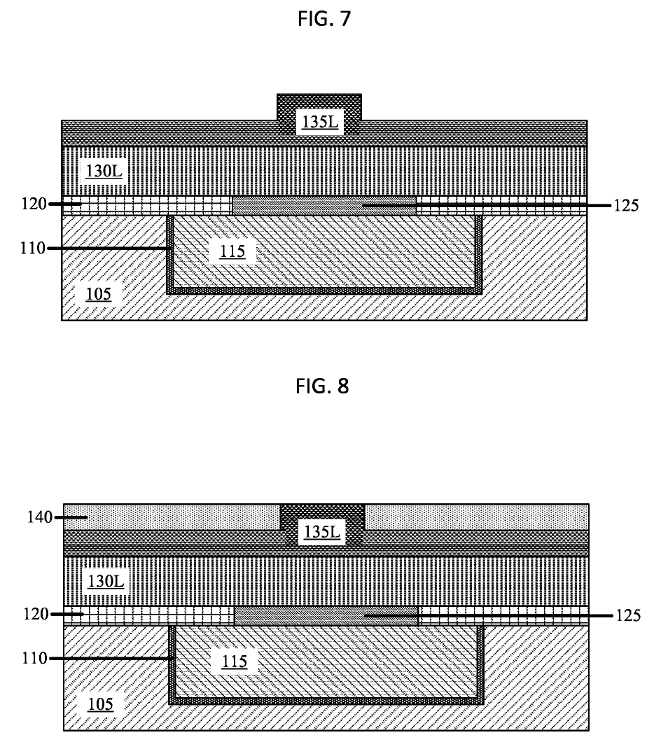

FIG. 7 illustrates the processing stage after a partial etching of the initial reference layer 135L. A lithography layer (not shown) is formed on top of the initial reference layer 135L. The lithography layer (not shown) is patterned, and an etching process is utilized to partially etch the initial reference layer 135L. The initial reference layer 135L is patterned to form a raised section that is located above/vertically aligned with the metal cap 125. The lithography layer (not shown) is removed to expose the raised section of the initial reference layer 135L. FIG. 8 illustrates the processing stage after the formation of a first spacer 140. A first spacer 140 is formed on top of the initial reference layer 135L. The first spacer 140 is planarized to expose a top surface of the raised section of the initial reference layer 135L. Therefore, the top surface of the first spacer 140 and the top surface of the raised section of the initial reference layer 135L forms a substantially uniform flat surface profile. The first spacer 140 is comprised of a first dielectric material, for example, an oxide, nitride, SiN, or another suitable dielectric material.

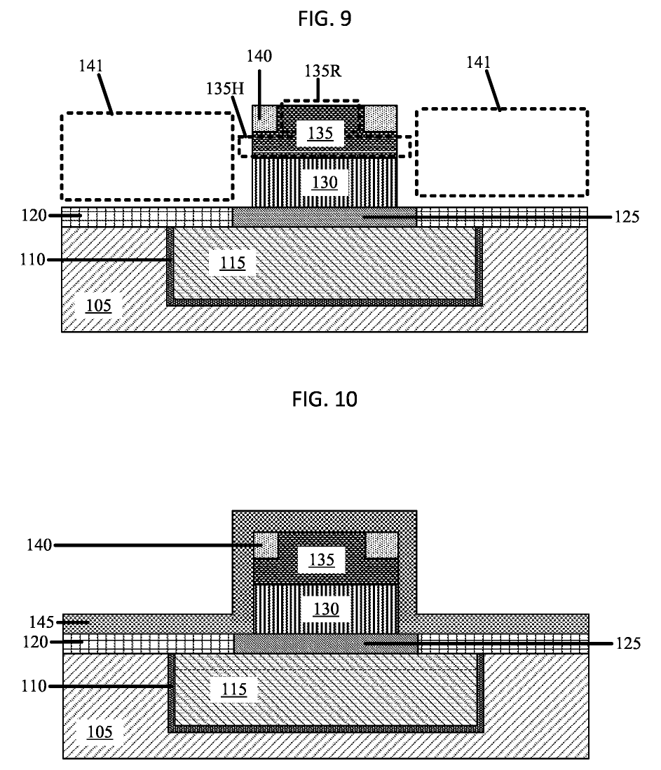

FIG. 9 illustrates the processing stage after etching of the first spacer 140, the initial reference layer 135L, and the bottom electrode layer 130L to form the bottom section of the MRAM cell. A lithography layer (not shown) is formed on top of the first spacer 140 and the raised section of the initial reference layer 135L. The lithography layer (not shown) is patterned for the formation of the bottom section of the MRAM cell. The first spacer 140, the initial reference layer 135L, and the bottom electrode layer 130L are etched to form the bottom section of the MRAM cell. The bottom section of the MRAM cell includes a bottom electrode 130, a reference layer 135, and the first spacer 140. The etching process exposes portions of the cap layer 120 and metal cap 125. The reference layer 135 has a horizontal section 135H and a raised section 135R. The raised section 135R extends vertically from the horizontal section 135H. The horizontal section 135H is wider or has a larger width dimension (as illustrated) than the raised section 135R of reference layer 135. The width difference forms a plateau or step between the horizontal section 135H and the raised section 135R of reference layer 135. The first spacer 140 is located on the step or plateau, such that the remaining portions of the first spacer 140 is located on top of the horizontal section 135H and laterally adjacent to the raised section 135R of the reference layer 135. Since the bottom electrode 130 and reference layer 135 are etched to form the bottom section of the MRAM cell prior to the formation of the tunnel barrier, they are prevented from back sputtering etched material on to the sides of the tunnel barrier which could lead to shorts.

Dashed box 141 emphasizes the low aspect ratio valleys or trenches that are formed between adjacent bottom sections of adjacent MRAM cells. FIG. 9 only illustrates one bottom section of one MRAM cell, this is done for simplicity reason only. It would have been obvious to one of ordinary skill in the art that an MRAM array includes multiple MRAM cells, and that each of the MRAM cells are located adjacent to another MRAM cell. As seen below, FIG. 12 illustrates two adjacent bottom sections of adjacent MRAM cells, which will be described in further detail below. The dimensions of these low aspect ratio valleys or trenches (as emphasized by dashed box 141) are determined by the height of the bottom sections of the MRAM cells.

FIG. 10 illustrates the processing stage after the formation of a second spacer 145. The second spacer 145 is formed on the exposed surfaces of the cap layer 120, the metal cap 125, and around the exposed surfaces of the bottom section of the MRAM cell. The second spacer 145 encapsulates the bottom section of the MRAM cell, such that the second spacer 140 is located along the vertical side walls and the top surface of the bottom section of the MRAM cell. The second spacer 145 is comprised of a second dielectric material, for example, an oxide, nitride, SiN, or another suitable dielectric material. The first spacer 140 and the second spacer 145 can be comprised of the same dielectric material or be comprised of different dielectric materials.

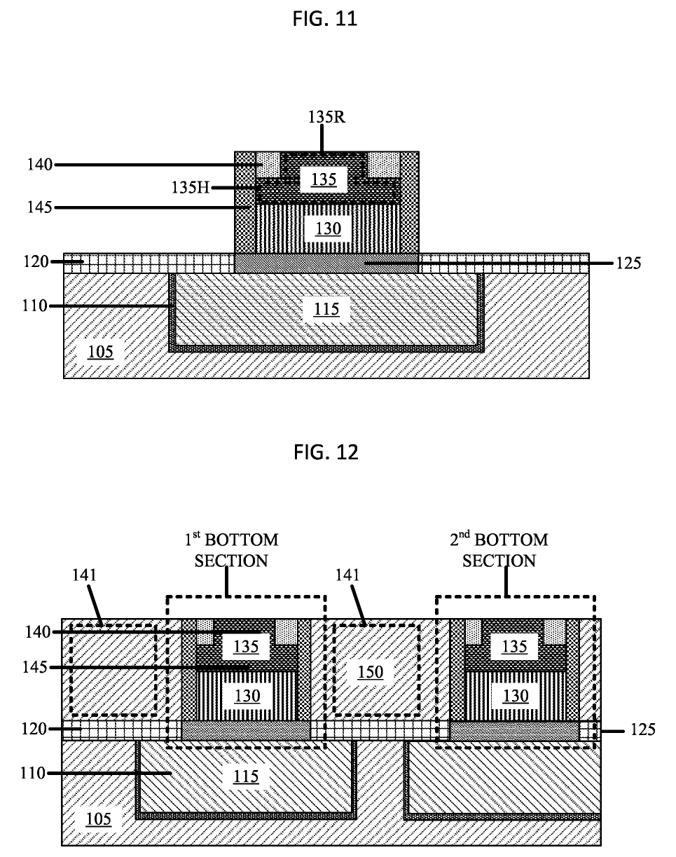

FIG. 11 illustrates the processing stage after the etching of the second spacer 145. The second spacer 145 was etched back to remove unnecessary portions of the second spacer 145. The second spacer 145 that was located on top of the bottom section of the MRAM cell is removed to expose the top surface of the first spacer 140 and a top surface of the raised section 135R of reference layer 135. Additionally, the second spacer 145 that is located on top of the cap layer 120 and located between adjacent bottom sections of MRAM cells is removed. Vertical portions of the second spacer 145 that remain are located on the vertical sides of the bottom section of the MRAM cell. The vertical portions of the second spacer 145 enclose/cover the vertical sides of the bottom electrode 130 and the vertical sides of the horizontal section 135H of the reference layer 135. The vertical portions of the second spacer 145 protect the bottom electrode 130 and the reference layer 135 from being etched or damaged during downstream processes. Additionally, the second spacer 145 prevents any back sputtered material from being deposited on the vertical sides of the bottom electrode 130 and the vertical sides of the horizontal section 135H of the reference layer.

FIG. 12 illustrates the processing stage after formation and planarization of a bottom interlayer dielectric layer 150. A bottom interlayer dielectric layer 150 is formed on the exposed surfaces to fill in the low aspect ratio valley or trench (as emphasized by dashed box 141) that is located between adjacent bottom sections of adjacent MRAM cells. A planarization process is utilized to planarize the bottom interlayer dielectric layer 150 to remove excess material and to expose the top surface of the bottom section of the MRAM cells. FIG. 12 illustrates a 1^{st} bottom section and an adjacent 2^{nd} bottom section. At this point during process, adjacent MRAM cells have a low aspect ratio valley or trench (as emphasized by dashed box 141) that separates the adjacent bottoms sections of adjacent MRAM cells, so the filling of these low aspect ratio valleys or trenches located between adjacent MRAM bottom sections with the bottom interlayer dielectric layer 150 does not lead to collapse or damage of the bottom sections of the MRAM cells.

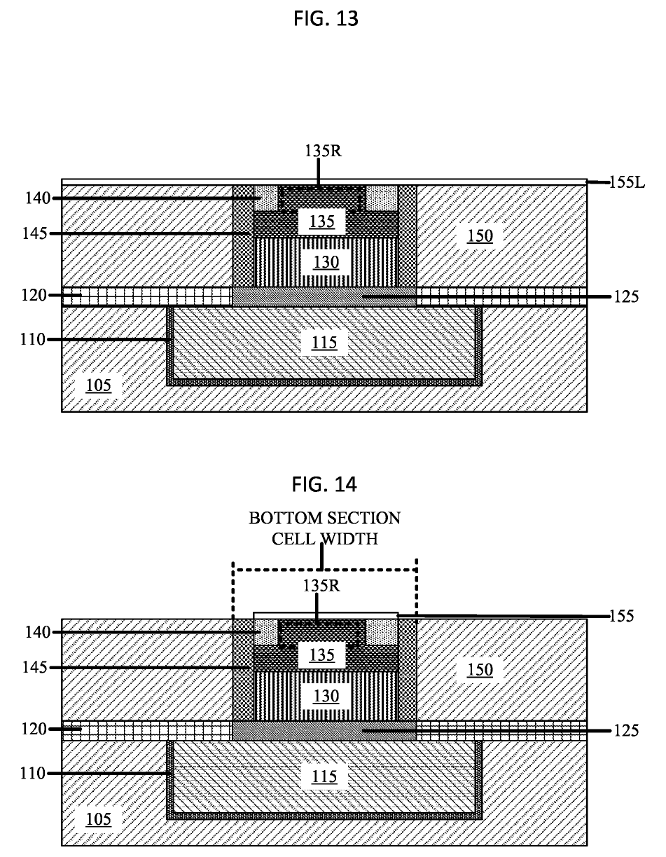

FIG. 13 illustrates the processing stage after the formation of the tunnel barrier layer 155L. The tunnel barrier layer 155L is formed on top of the bottom section of the MRAM cell (i.e., the top surface of the first spacer 140, the top surface of the second spacer 145, the top surface of the raised section 135R of the reference layer 135), and on top of the top surface of the bottom interlayer dielectric layer 150. The tunnel barrier layer 155L can be selected from a group that includes MgO or Al₂O₃. FIG. 14 illustrates the processing stage after the patterning of the tunnel barrier layer 155L to form the tunnel barrier 155. The tunnel barrier layer 155L is patterned to form the tunnel barrier 155 located on top of each of the bottom sections of the MRAM cell. The tunnel barrier 155 has a width greater than the raised section 135R of the reference layer 135 and the tunnel barrier 155 has a width that is less than the width of the bottom section of the MRAM cell.

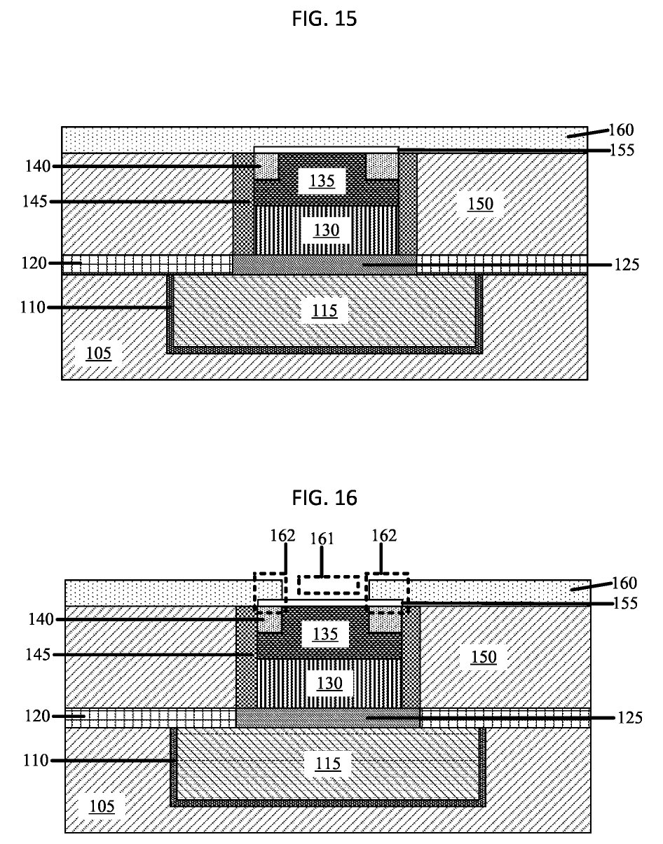

FIG. 15 illustrates the processing stage after the formation of a third spacer 160. The third spacer 160 is formed on the top surfaces of the bottom interlayer dielectric layer 150, the second spacer 145, tunnel barrier 155, and possibly on top of the first spacer 140. The third spacer 160 encloses the tunnel barrier 155, such that the third spacer 160 is in contact with the side surfaces and the top surface of the tunnel barrier 155. The third spacer 160 is comprised of a second dielectric material, for example, an oxide, nitride, SiN, or another suitable dielectric material. The third spacer 160, the first spacer 140, and the second spacer 145 can be comprised of the same dielectric material, be comprised of different dielectric materials, or any combination thereof. FIG. 16 illustrates the processing stage after the pattering of the third spacer 160, where the patterning forms trench 161 in the third spacer 160. Trench 161 exposes a portion of the top surface of the tunnel barrier 155 but trench 161 does not expose the entirety of top surface of the tunnel barrier 155. Trench 161 does not expose the end portions of the tunnel barrier 155. Dashed box 162 emphasizes the end portions of the tunnel barrier 155 that are still enclosed by the third spacer 160. A bottom surface of the end portions of the tunnel barrier 155 are in contact with the first spacer 140 and the top surface of the end portions of the tunnel barrier 155 are in contact with the third spacer 160 (as emphasized by dashed box 162). The trench 161 or channel creates a valley within the third spacer 160, such that there is a height difference between the top surface of the third spacer 160 and the exposed top surface of the tunnel barrier 155.

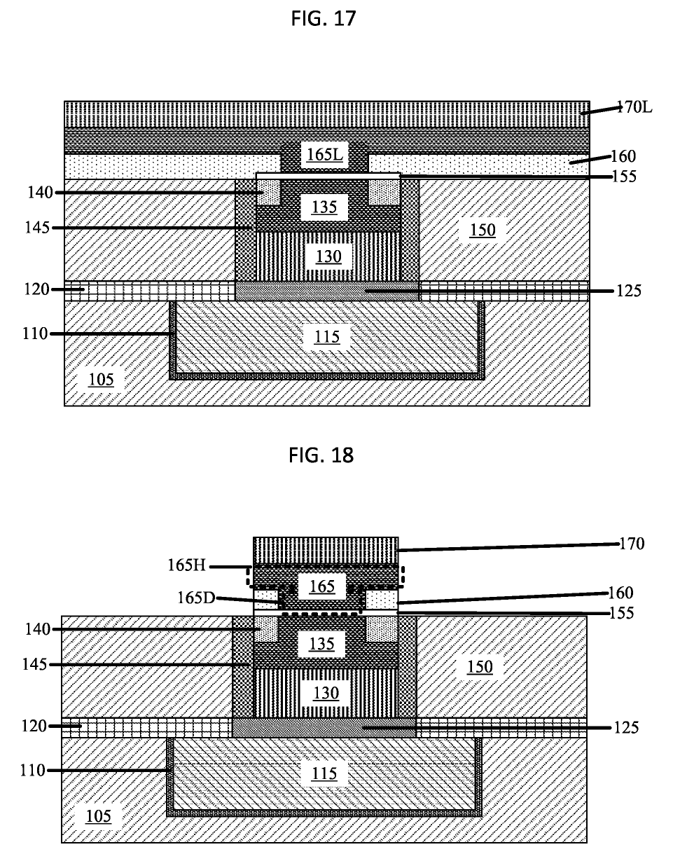

FIG. 17 illustrates the processing stage after the formation of the initial free layer 165L and the formation of the top electrode layer 170L. The initial free layer 165L is formed on top of the third spacer 160 and fills trench 161. The initial free layer 165L is in contact with the top surface of the tunnel barrier 155 that formed the bottom boundary of the trench 161. The initial free layer 165L can be selected from a group that includes CoFeB multi-layers with Mo, Pt, or Ta. A top electrode layer 170L is formed on top of the initial free layer 165L. The top electrode layer 170L can be selected from a group that includes Nb, NbN, W, WN, Ta, TaN, Ti, TiN, Ru, Cu, W, Mo, Cr, V, Pd, Pt, Rh, Sc, Al, other high melting point metals, other suitable conductive metals, conductive alloys, or a combination thereof. FIG. 18 illustrates the processing stage after etching the top electrode layer 170L and the initial reference layer 165L. The top electrode layer 170 and the initial reference layer 165L are etched to form the top section of the MRAM cell that are associated with each of the MRAM cells. A top section of the MRAM cell are formed on each of the bottom section MRAM cells that comprise the MRAM array (not shown). Only one MRAM cell (that includes a bottom section and a top section) are illustrated, this is done for simplicity reasons only to illustrate the process for independently forming the bottom and top sections of the MRAM cell. The etching of the top electrode layer 170L and the initial free layer 165L also etches the third spacer 160. Each top section of the MRAM cell (only one top section is illustrated for simplicity reasons) includes a portion of the third spacer 160, a free layer 165, and a top electrode. The free layer 165 includes a horizontal section 165H and a downward section 165D. The downwards section 165D extends downwards from the horizontal section 165H, such that the downward section 165D of the free layer 165 is aligned with the raised section 135R of reference layer 135. The downward section 165D of the free layer 165 has a width that is smaller than the width of the horizontal section 165H of the free layer 165. The width difference between the downward section 165D and the horizontal section 165H of the free layer 165 creates an overhang area where a portion of the third spacer 160 remains. The remaining portion of the third spacer 160 is located on a top surface of the end portions of the tunnel barrier 155, such that the remaining portion of the third spacer 160 is in contact with a bottom surface of the horizontal section 165H and a vertical side surface of the downward section 165D of the free layer 165. The downward section 165D of the free layer 165 has a width that is less than the width of the tunnel barrier layer 155.

The etching process further exposes a side surface of the tunnel barrier 155, however there is reduced chance of back sputtered damage/shorts being formed that are caused by the etching process depositing material on the side surface of the tunnel barrier 155 and forming a connection with another layer. This back sputtered damage/shorts is mitigated by the fact the third spacer 160, first spacer 140, and the second spacer 145 are located around the end portions of the tunnel barrier 155, so if these dielectric/spacer materials are sputtered back on the end portions of the tunnel barrier 155 then no damage/shorts will be formed.

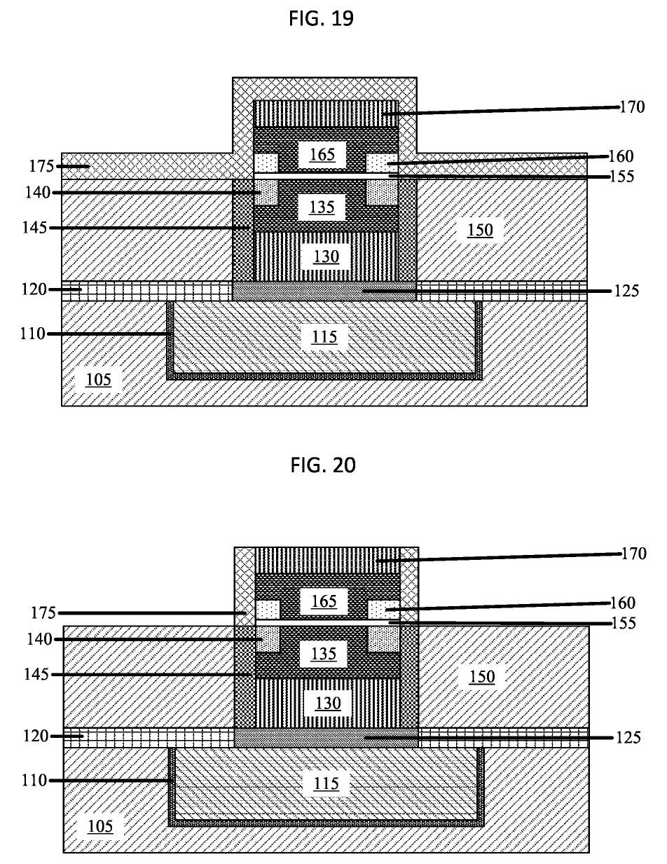

FIG. 19 illustrates the processing stage after the formation of a fourth spacer 175. The fourth spacer 175 is formed on the exposed surfaces of the bottom interlayer dielectric layer 150, on top of the second spacer 145, and around the exposed surfaces of the top section of the MRAM cell (i.e., the end portion of the tunnel barrier 155, the third spacer 160, the vertical sides of the horizontal section 165H of the free layer 165, the top electrode 170). The fourth spacer 175 or an encapsulation layer is located around the top section of the MRAM cell and is in contact with the tunnel barrier 155. The fourth spacer 175 is comprised of a second dielectric material, for example, an oxide, nitride, SiN, or another suitable dielectric material. The fourth spacer 175, the first spacer 140, the second spacer 145, and the third spacer 160 can be comprised of the same dielectric material, be comprised of different dielectric materials, or any combination thereof.

FIG. 20 illustrates the processing stage after the etch back of the fourth spacer 175. The fourth spacer 175 is etched back to remove excess material. The etch back of the fourth spacer 175 exposes a top surface of the bottom interlayer dielectric layer 150 and a top surface of the top electrode 170. Vertical sections of the fourth spacer 175 remain located adjacent to side surfaces of the top section of the MRAM cell (e.g., the tunnel barrier 155, the third spacer 160, the free layer 165, and the top electrode 170). The fourth spacer 175 will now be considered part of the top section of the MRAM cell.

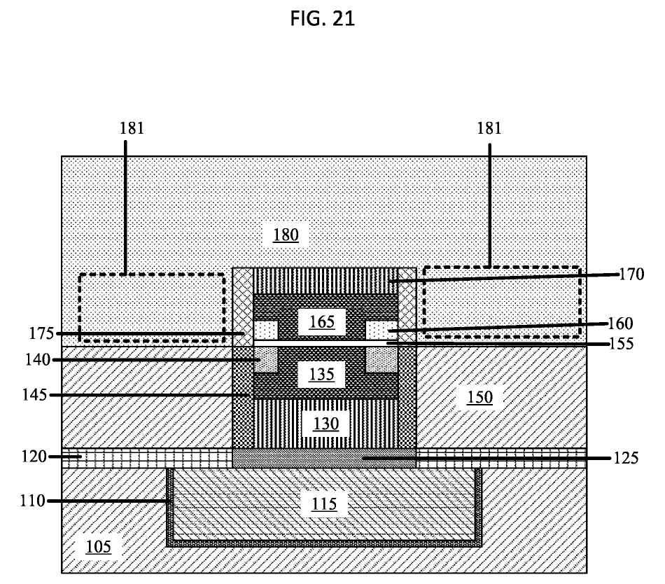

FIG. 21 illustrates the processing stage after the formation of the top interlayer dielectric layer 180. Top interlayer dielectric layer 180 is formed on top of the bottom interlayer dielectric layer 150 and formed on the sides and on top section of the MRAM cell (e.g., the vertical side of the fourth spacer 175, the top surfaces of the fourth spacer 175 and the top surface of the top electrode 170). The top interlayer dielectric layer 180 can be comprised of the same dielectric materials as the bottom interlayer dielectric layer 150 or it can be comprised of a different dielectric material. MRAM cell collapse or falling down which are caused by the formation of the interlayer dielectric layer are avoided by the present invention, The MRAM cell collapse is avoided because when forming the top interlayer dielectric layer 180, the dielectric material does not have to fill a high aspect ratio valley that are located between adjacent MRAM cells, but instead the top interlayer dielectric layer 180 fills in low aspect ratio valleys. Dashed box 181 emphasizes the low aspect ratio top section valley/space that is located between adjacent MRAM cells. The bottom interlayer dielectric layer 150 has filled in the bottom section of the valley/space that is located between adjacent MRAM cells, such that the top interlayer dielectric layer 180 only needs to fill in the top section of the valley/space that is located between adjacent MRAM cells.

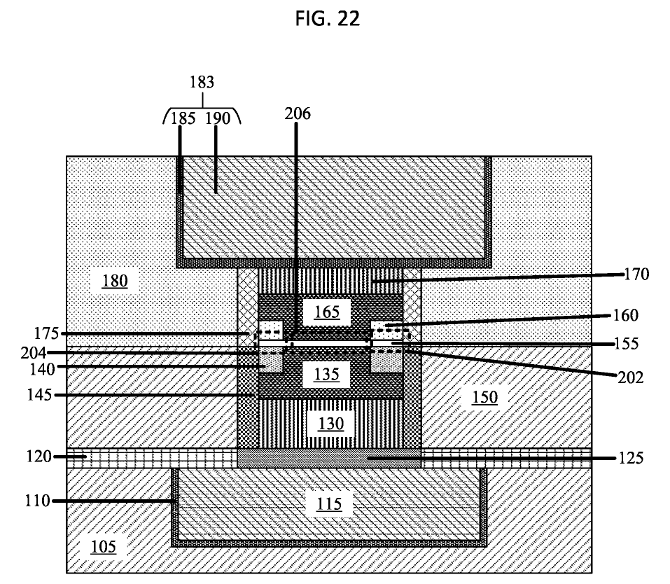

FIG. 22 illustrates the processing stage after the formation of the top connector 183. A top connector 183 includes a top metal liner 185 and a top metal fill 190. A trench (not shown) is formed in the top interlayer dielectric layer 180 that exposes a top surface of the top electrode 170. The trench (not shown) is lined with the top metal liner 185 and filled with the top metal fill 190 to form the top connector 183. The present invention only illustrates one MRAM cell that was formed by creating the bottom section and top section for simplicity reason only. It is well understood that this present invention can be applied to the formation of a plurality of MRAM cells to form an MRAM array. The bottom section of the MRAM cell includes the bottom electrode 130, the reference layer 135, the first spacer 140, and the second spacer 145. If the first spacer 140 and the second spacer 145 are comprised of the same material, then it will form one continuous spacer. The top section of the MRAM cell includes the tunnel barrier 155, the free layer 165, the top electrode 170, the third spacer 160, and the fourth spacer 175. If the third spacer 160 and the fourth spacer 175 are comprised of the same material, then it will form one continuous spacer. Additionally, if the first spacer 140, the second spacer 145, the third spacer 160, and the fourth spacer 175 are comprised of the same material then one continuous spacer will be formed. The FIGS. 1-22 use different patterns to illustrate the different spacers to highlight when the different spacers are formed.

Dashed boxes 202 and 204 emphasize the end portions of the tunnel barrier 155 that are enclosed by the spacers (e.g., the first spacer 140, the second spacer 145, the third spacer 160, and the fourth spacer 175). Dashed box 206 emphasizes the central or middle portion of the tunnel barrier 155 that is in contact with a top surface of the raised section 135R of the reference layer 135 and a bottom surface of the downward section 165D of the free layer 165. The first spacer 140 and the second spacer 145 prevent shorts from forming on the tunnel barrier 155 from back sputtering of etched materials during the etching of the tunnel barrier 155. The third spacer 160 prevents the shorts from forming on the tunnel barrier 155 during the etching of the initial free layer 165L and the top electrode layer 170L. As emphasized by dashed boxes 202 and 204, the end portions of the tunnel barrier 155 are enclosed by spacers (e.g., the first spacer 140, the second spacer 145, the third spacer 160, and the fourth spacer 175), thus preventing any back sputtered material that is deposited on the vertical side surface of the tunnel barrier 155 from making a connection with either the free layer 165 or the reference layer 135.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A magnetoresistive-random-access-memory (MRAM) cell structure comprising:
a bottom electrode;
a reference layer located on top of the bottom electrode;
a tunnel barrier located on top of the reference layer, wherein the tunnel barrier includes a middle portion and an end portion;
a free layer located on top of the tunnel barrier;
a top electrode located on top of the free layer; and
a spacer that encloses the end portion of the tunnel barrier.

2. The MRAM cell of claim 1, wherein the spacer is in contact with a top surface of the end portion of the tunnel barrier.

3. The MRAM cell of claim 1, wherein the spacer is in contact with a bottom surface of the end portion of the tunnel barrier.

4. The MRAM cell of claim 1, wherein the spacer is in contact with multiple surfaces of the end portion of the tunnel barrier.

5. The MRAM cell of claim 1, wherein the spacer is in contact with a plurality of different surfaces of the reference layer.

6. The MRAM cell of claim 1, wherein the spacer is in contact with a plurality of different surfaces of the free layer.

7. A magnetoresistive-random-access-memory (MRAM) cell structure comprising:
a bottom electrode;
a reference layer located on top of the bottom electrode, wherein the reference layer includes a horizontal section and a raised section;
a tunnel barrier located on top of the reference layer, wherein the tunnel barrier includes a middle portion and an end portion;
a free layer located on top of the tunnel barrier;
a top electrode located on top of the free layer; and
a spacer that encloses the end portion of the tunnel barrier.

8. The MRAM cell of claim 7, wherein the spacer is in contact with a top surface of the end portion of the tunnel barrier, wherein the spacer is in contact with a bottom surface of the end portion of the tunnel barrier.

9. The MRAM cell of claim 7, wherein the spacer is in contact with a plurality of different surfaces of the reference layer.

10. The MRAM cell of claim 7, wherein the spacer is in contact with a plurality of different surfaces of the free layer.

11. The MRAM cell of claim 7, wherein the raised section of the reference layer has a width that is less than the horizontal section of the reference layer.

12. The MRAM cell of claim 11, wherein the middle section of the tunnel barrier is in contact with a top surface of the raised section of the reference layer.

13. The MRAM cell of claim 12, wherein the tunnel barrier is wider than the raised section of the reference layer.

14. The MRAM cell of claim 13, wherein the spacer is in contact with a top surface of the horizontal section of the reference layer and the spacer is in contact with a vertical side surface of the raised section of the reference layer.

15. A magnetoresistive-random-access-memory (MRAM) cell structure comprising:
a bottom electrode;
a reference layer located on top of the bottom electrode;
a tunnel barrier located on top of the reference layer, wherein the tunnel barrier includes a middle portion and an end portion;
a free layer located on top of the tunnel barrier, wherein the free layer includes a horizontal section and a downward section;
a top electrode located on top of the free layer; and
a spacer that encloses the end portion of the tunnel barrier.

16. The MRAM cell of claim 15, wherein the spacer is in contact with a top surface of the end portion of the tunnel barrier, wherein the spacer is in contact with a bottom surface of the end portion of the tunnel barrier.

17. The MRAM cell of claim 15, wherein the spacer is in contact with a plurality of different surfaces of the reference layer, and wherein the spacer is in contact with a plurality of different surfaces of the free layer.

18. The MRAM cell of claim 15, wherein the downward section of the free layer has a width that is less than the horizontal section of the free layer.

19. The MRAM cell of claim 18, wherein the middle section of the tunnel barrier is in contact with a bottom surface of the downward section of the free layer, wherein the tunnel barrier is wider than the downward section of the free layer.

20. The MRAM cell of claim 19, wherein the spacer is in contact with a bottom surface of the horizontal section of the free layer and the spacer is in contact with a vertical side surface of the downward section of the free layer.
